(19) United States
(12) Patent Application Publication
(10) Pub. No.: US 2018/0052632 A1
(43) Pub. Date: Feb. 22, 2018

(54) STORAGE SYSTEM AND STORAGE CONTROL METHOD

(71) Applicant: Hitachi, Ltd., Tokyo (JP)

(72) Inventors: Masanori TAKADA, Tokyo (JP); Naoya OKADA, Tokyo (JP); Mitsuo DATE, Tokyo (JP); Tsutomu KOGA, Tokyo (JP)

(21) Appl. No.: 15/552,509

(22) PCT Filed: May 11, 2015
(86) PCT No.: PCT/JP2015/063507

§ 371 Date: Aug. 22, 2017

(51) Int. Cl. G06F 3/06; G06F 13/12; G11C 7/10

(52) U.S. Cl. CPC G06F 3/0644; G11C 7/1078; G06F 3/0659; G06F 13/12

(57) ABSTRACT

This storage system includes a processor, a memory, a storage drive, and an interface device. The storage drive determines a size of transfer data based on an offset value which is a value relating to a size between the beginning of a storage area in the memory for the transfer of the data to be transferred to the interface device and the beginning of the partition of the memory to which the beginning of the storage area belongs, and then transfers data to be transferred, which has the determined size, to the interface device. The interface device divides the transferred data into packets and transfers these packets to the processor. The processor then stores the packets transferred from the interface device in the memory on a unit of a partition.

### TECHNICAL FIELD

The present invention generally relates to storage control and relates to, for example, technologies of a storage system and a storage control method.

### BACKGROUND ART

An SAS adapter for mutual conversion between PCIe (PCI-Express) protocol and SAS (Serial Attached SCSI) protocol is known (PTL 1). The SAS adapter is provided between a processor and a storage drive (HDD (Hard Disk Drive), for example), and converts data transferred from the storage drive based on the SAS protocol to the PCIe protocol and transfers to the processor. The processor divides the data transferred from the SAS adapter into units of data each having a predetermined size and writes them into a memory (DRAM (Dynamic Random Access Memory), for example).

### CITATION LIST

### Patent Literature

[PTL 1] Japanese Patent Laid-Open No. 2012-133405

### SUMMARY OF INVENTION

### Technical Problem

A processor manages a memory area divided into partitions each having a predetermined size and writes data on a unit of the partition. Therefore, when existing data is present in a part of the partition of the memory at a storage destination of new data, the processor needs to execute such processing that it once reads data of a partition size (including the existing data) from that partition, updates the read data (adds or overwrites the new data on the read data, for example) and writes the data after the update (data for the partition size) on that partition. This processing is called “read-modify-write”. This processing takes time longer than that for processing of only writing data in that partition. This incurs a throughput degradation of the storage system. The similar problem can occur not only in PCIe and SAS. Thus, an object of this invention is to improve the throughput of the storage system.

### Solution to Problem

A storage system according to an embodiment includes a processor, a memory accessed on a unit of a partition, a storage drive, and an interface device interfacing data communication between the processor and the storage drive, the partition having a predetermined size.

The storage drive determines a size of transfer data based on an offset value which is a value relating to the size between a storage area in the memory for the transfer data to be transferred to the interface device and a predetermined position of the partition in the memory to which at least a part of the storage area belongs, and transfers the transfer data of the determined size to the interface device.

The interface device divides the transfer data into packets and transfers them to the processor.

The processor stores the packet transferred from the interface device in the memory on a unit of a partition.

### Advantageous Effects of Invention

According to the present invention, a throughput of the storage system can be improved.

### BRIEF DESCRIPTION OF DRAWINGS

FIG. 1 illustrates a configuration example of a storage system.

FIG. 2 illustrates a storage example of data in a memory.

FIG. 3 is a sequence chart illustrating a processing example notifying a size of a cache line to a drive.

FIG. 4 is a sequence chart illustrating a processing example of requesting read from the drive.

FIG. 5 is a flowchart illustrating a processing example of the drive.

FIG. 6 illustrates a processing example in which the data read from the drive is stored in the memory.

FIG. 7 illustrates a configuration example of a command management list.

FIG. 8 illustrates a configuration example of SGL (Scatter Gather List).

FIG. 9 illustrates a configuration example of a command-in-process management list and a SGL cache.

FIG. 10 is a flowchart illustrating a processing example of an SAS adapter.

FIG. 11 is a sequence chart illustrating a processing example in which the data read from the drive is stored in the memory through the SAS adapter.

FIG. 12 is a flowchart illustrating a processing example of the drive.

FIG. 13 is a flowchart illustrating a processing example of the SAS adapter.

FIG. 14 is a sequence chart illustrating a processing example in which the data read from the drive is stored in the memory through the SAS adapter.

### DESCRIPTION OF EMBODIMENTS

Several embodiments will be described below by referring to the attached drawings. In the following description, information is described with an expression “xxx table” but the information may be expressed in any data structure. That is, in order to indicate that the information does not rely on the data structure, the “xxx table” can be called “xxx information”. Moreover, in the following description, configuration of each table is an example, and one table may be divided into two or more tables or the whole of or a part of two or more tables may be one table. Moreover, in the following description, an ID is used as identification information of an element, but other types of identification information may be used instead of or in addition to that. Moreover, in the following description, in a case of description without discriminating the same kinds of elements, a common number in the reference numeral is used, while in a case of description by discriminating the same kinds of elements, the reference numeral of the element is used in some cases. For example, in the case of description without discriminating individual elements, it may be described as “xxx 212”, while in the case of description by discriminating individual elements, it may be described as “xxx 212a”. Moreover, in the following description, an I/O (Input/Output) request is a write request or a read request, and it may be also called an access request.

### Embodiment 1

Embodiment 1 is an example in which a drive 3 determines a size of transfer data by considering a state of a partition of a memory 5 in which the transfer data is to be stored.

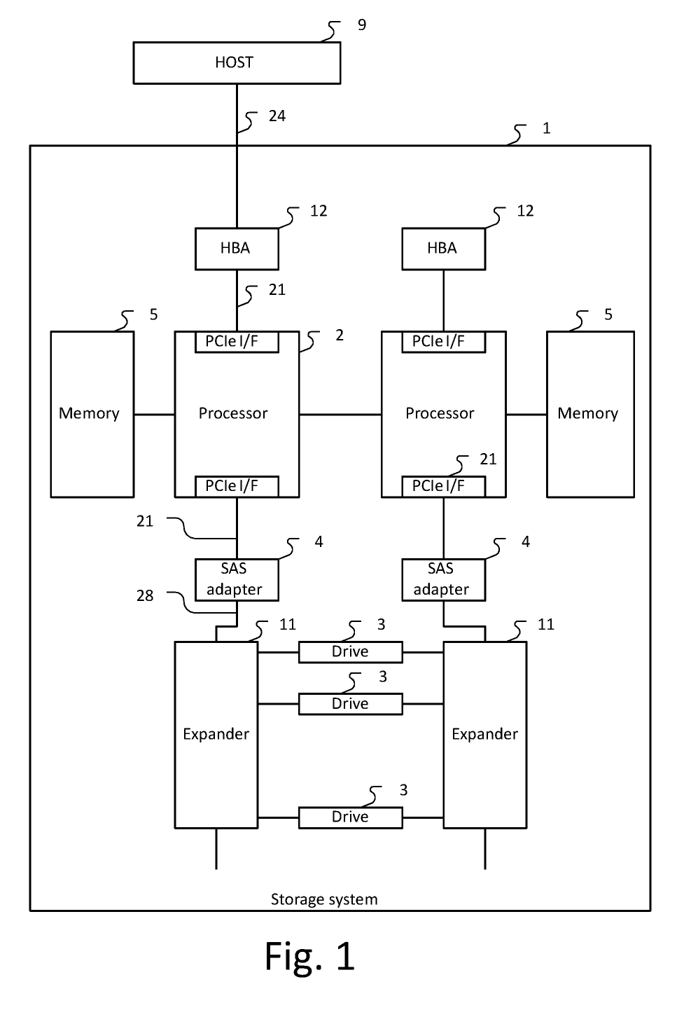

FIG. 1 illustrates a configuration example of a storage system 1 according to the embodiment 1.

The storage system 1 is accessed from a host computer 9 through a network 24 (or a cable). An example of the network 24 is FC-SAN (FibreChannel Storage Area Network). The storage system 1 may include a processor 2, a memory 5, an HBA (Host Bus Adapter) 12, an SAS adapter 4, an SAS expander 11, and the drive 3. The processor 2, the memory 5, the HBA 12, and the SAS adapter 4 may be coupled by an internal bus 21 capable of bilateral communication. Each element coupled to the internal bus 21 may be communicable by the PCIe protocol.

The HBA 12 may be connected to the network 24. The HBA 12 may have a function of mutual conversion between an FC protocol relating to the network 24 and the PCIe protocol relating to the internal bus 21.

The processor 2 controls transactions of data between the host computer 9 and the drive 3. When the processor 2 receives a read request from the host computer 9 through the HBA 12, it reads data corresponding to the read request from the drive 3 and returns it to the host computer 9. At this time, the processor 2 may temporarily store (cache) the data read from the drive 3 in the memory 5. The memory 5 may be a storage device with an I/O performance higher than the drive 3. An example of the memory 3 is DRAM (Dynamic Random Access Memory), MRAM (Magnetoresistive Random Access Memory) or FeRAM (Ferroelectric Random Access Memory).

The drive 3 has a non-volatile storage medium and holds the data in the storage medium. When the drive 3 receives a read command, it reads data corresponding to the read command from the storage medium and returns it. The drive 3 may be controlled by the SAS protocol. An example of the drive 3 is an HDD, an SSD (Solid State Drive), and a flash device. The drive 3 may be a logical drive configured by one or more physical drives. Moreover, the drive 3 may be a logical storage volume. The drive 3 may be a RAID (Redundant Arrays of Inexpensive Disks) group configured by a plurality of drives. Processing of the drive 3 in the embodiment may be executed by a controller provided in the drive 3. Moreover, the drive 3 may include a memory therein.

The SAS adapter 4 is an example of an interface device. To the SAS adapter 4, the drive 3 is coupled through a cable 28 (or the network) capable of bilateral communication. To the SAS adapter 4, a plurality of drives 3 may be coupled through the SAS expander 11. The SAS adapter 4 and the drive 3 may be communicable with each other by the SAS protocol. Moreover, to the SAS adapter 4, the processor 2 is coupled through the internal bus 21 as described above. The SAS adapter 4 and the processor 2 may be communicable with each other by the PCIe protocol. The SAS adapter 4 may have a function of mutual conversion between the PCIe protocol and the SAS protocol. Processing of the SAS adapter 4 in the embodiment may be executed by an LSI provided in the SAS adapter 4. Moreover, the SAS adapter 4 may include a memory therein.

The SAS adapter 4 may convert the read command issued from the processor 2 based on the PCIe protocol to the SAS protocol and transfer it to the drive 3. Moreover, the SAS adapter 4 may convert the read data transferred from the drive 3 based on the SAS protocol to the PCIe protocol and transfer it to the processor 2. The processor 2 may store this transferred read data in the memory 5.

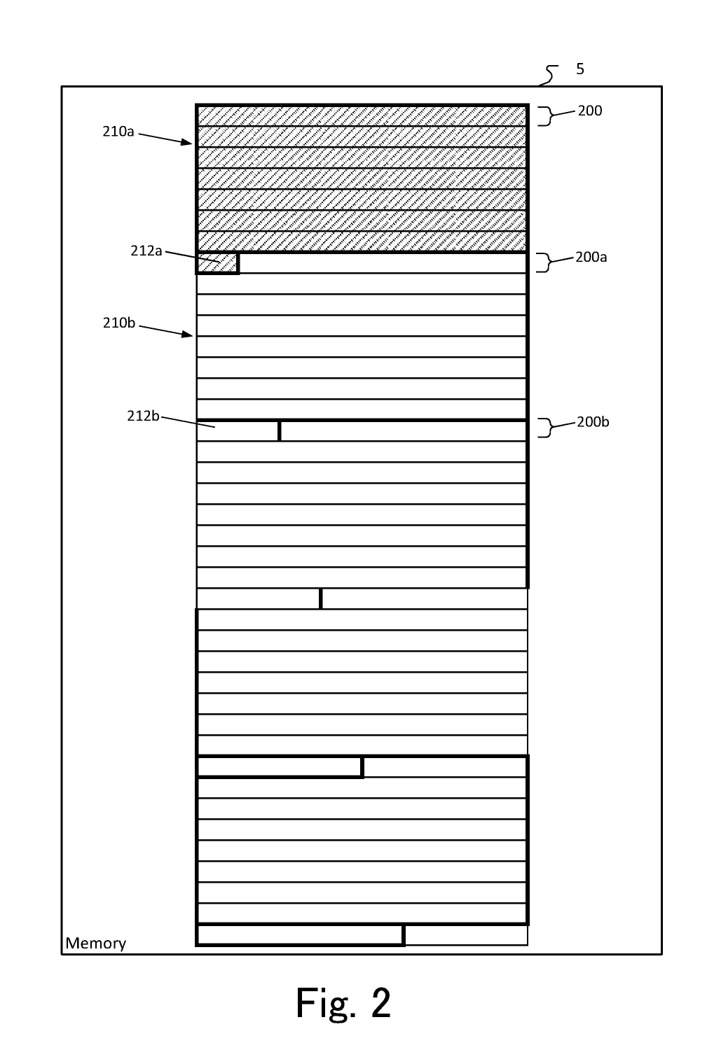

FIG. 2 illustrates an example of write processing of data with respect to the memory 5.

An access can be made to the drive 3 on a unit of sector. In this embodiment, a case where 520 bytes in which 8-byte DIF (Data Integrity Field) data is added to 512-byte user data is 1 sector will be described. The example of the DIF data is CRC (Cyclic Redundancy Check) for detecting an error in the user data and address information for preventing a handling error of the user data. The data stored in 1 sector will be described as “sector data” below.

An area of the memory 5 is managed by being divided into partitions each having a predetermined size. This partition having the predetermined size is called a cache line 200. The processor 2 makes an access on a unit of a cache line 200. A size of 1 cache line 200 is power of 2 (64 bytes, 128 bytes, for example). In this embodiment, a case where the size of 1 cache line 200 is 64 bytes will be described.

Subsequently, a case where multiple pieces of the sector data are written in the memory 5 will be described by using FIG. 2. A first sector data 210a is written in cache lines 200 on first to eighth stages and an 8 byte portion (212a) in a cache line 200a on a ninth stage (shaded portion in FIG. 2) in the memory 5. A second sector data 210b is written in the remaining 56-byte portion in the cache line 200a on the ninth stage, the cache lines 200 on 10^{th} to 17^{th} stages, and a 16-byte portion (212b) in a cache line 200b on an 18^{th} stage.

When the data is to be written in the remaining 56-byte portion in the cache line 200a on the ninth stage, the processor 2 needs to execute such processing that it reads all the data stored in the cache line 200a on the ninth stage and replaces a 57-byte portion in a second half in all the read data with data for 56-byte portion from the beginning of the second sector data 210b and overwrites all the replaced data on the cache line 200a on the ninth stage. That is, in this case, the processor 2 needs to execute so-called read-modify-write on a unito of a cache line 200.

Therefore, when the size of the sector is not a multiple of the size of the cache line 200, a cache line 200 in which the data is stored only in a part thereof is generated. In order to store additional data in this cache line 200 in which the data is stored only in a part thereof, the processor 2 needs to execute the read-modify-write. Since the read-modify-write incurs a drop in a throughput of the storage system 1, it is preferably as small as possible. The storage system 1 according to this embodiment promotes improvement of the throughput by reducing the number of occurrences of this read-modify-write in the memory 5.

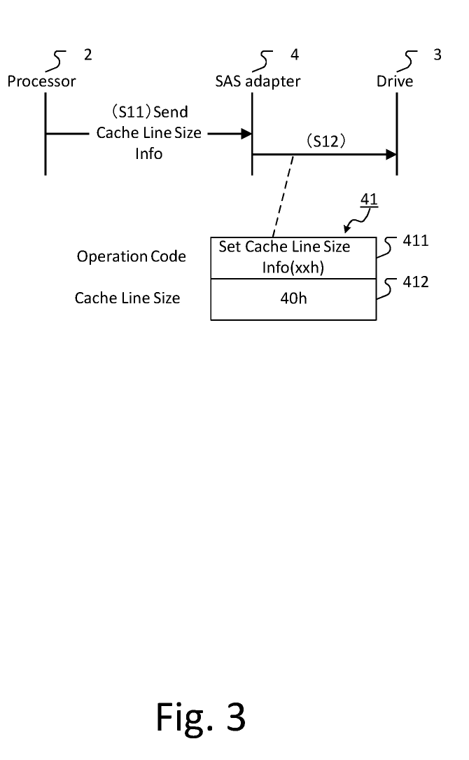

FIG. 3 is a sequence chart illustrating a processing example of notifying the size of the cache line 200 to the drive 3.

A cache-line size setting command 41 is a command for notifying the size of the cache line 200 to the drive 3. The cache-line size setting command 41 may include an operation code 411 and a cache line size 412. The operation code 411 is a code for identifying that the command is a “cache-line size setting command”. The cache line size 412 is a value indicating a size of the cache line 200. The cache-line size setting command 41 illustrated in FIG. 3 indicates that the cache line size 412 is “40 h (64 bytes)”.

The processor 2 transmits cache line size setting information to the SAS adapter 4 (Step S11). This cache line size setting information may include the size of the cache line 200. When the SAS adapter 4 receives the cache line size setting information from the processor 3, it transmits the cache-line size setting command 41 corresponding to the information to the drive 3 (Step S12).

By means of the aforementioned processing, the drive 3 can know the size of the cache line 200 of the memory 5. The processing illustrated in FIG. 3 may be included in initialization processing executed at start of the storage system 1. Alternatively, this processing may be included in predetermined processing executed when the drive 3 is increasingly provided in the storage system 1.

If the SAS adapter 4 knows the size of the cache line 200, the cache line size setting information to be transmitted from the processor 2 to the SAS adapter 4 does not have to include the size of the cache line 200.

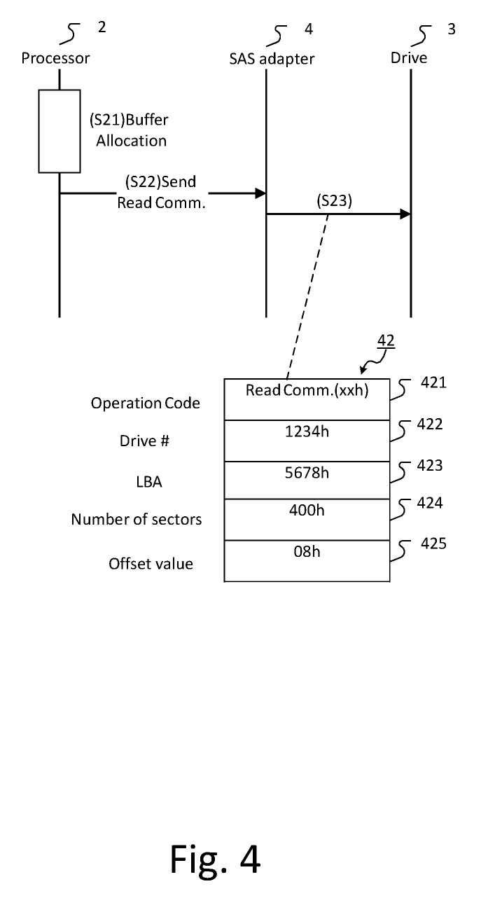

FIG. 4 is a sequence chart illustrating a processing example of requesting read data from the drive 3.

A read command 42 is a command of instructing transfer of the read data to the drive 3. The read command 42 may include an operation code 421, a drive number 422, an LBA 423, a data length 424, and an offset value 425. The operation code 421 is a code for identifying that the command is the “read command”. The drive number 422 is a number of the drive 3 to be read. The LBA 423 is a starting address of a sector of the read data. The number of sectors 424 is a sector number of the read data. That is, the sector data for the 424 sector number portions from the LBA 423 is the read data.

The offset value 425 is a value relating to a size between a storage area (a buffer area, for example) in the memory 5 of the transfer data to be transferred from the drive 3 and a predetermined position (a boundary of the cache line 200, for example) of a partition (the cache line 200, for example) in the memory 5 to which at least a part of the storage area (a beginning portion of the buffer area, for example) belongs. The offset value 425 may be a value indicating an offset amount of the beginning address of the buffer area reserved by the memory 5 from the boundary (beginning address) of the cache line 200. An example of the offset value 425 “08 h (8 bytes)” illustrated in FIG. 4 indicates that the beginning address of the buffer area is offset from the boundary (beginning address) of the cache line 200 by 8 bytes. In other words, it indicates that the beginning address of the buffer area is “the cache line size (64 bytes)×N stages (N is a positive integer)+8 bytes”.

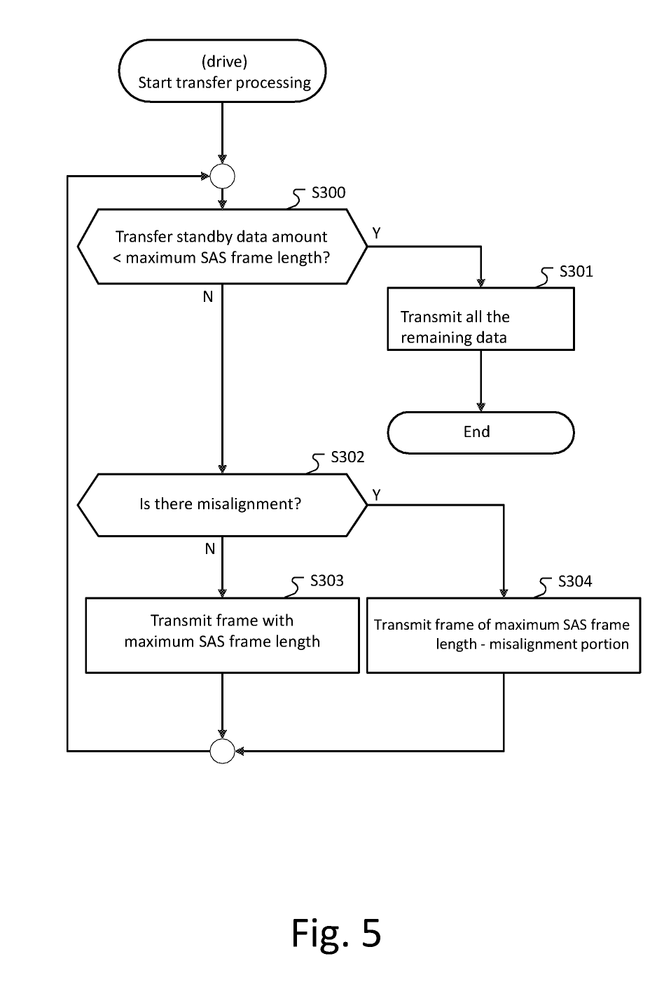

The processor 2 reserves the buffer area for storing the read data in the memory 5 (Step S21). Then, the processor 2 transmits read command information to the SAS adapter 4 (Step S22). When the SAS adapter 4 receives the read command information from the processor 2, it transmits the read command 42 corresponding to the information to the drive 3 (Step S23). This read command 42 is transmitted to the drive 3 corresponding to the drive number 422. The drive 3 having received this read command 42 executes processing illustrating in the following FIG. 5.

FIG. 5 is a flowchart illustrating a processing example of transfer of the read data by the drive 3 to the SAS adapter 4.

When the drive 3 receives the read command 42 from the SAS adapter 4, it reads data for the number of sectors 424 portions from the LBA 423 based on the read command 42 and stores it in a predetermined buffer memory in the drive 3. The drive 3 may transmit a connection request to the SAS adapter 4 at timing when it enters a transfer standby state (at timing when a predetermined amount or more of data is stored in the buffer memory, for example). As a result, a connection for transmitting an SAS frame is formed between the drive 3 and the SAS adapter 4. Then, the drive 3 may execute transmission processing of the data as follows.

The drive 3 determines whether a data amount of transfer standby (a data amount having been stored in the buffer memory, for example) is smaller than a maximum length that the SAS frame can take (hereinafter referred to as a “maximum SAS frame length”) or not (Step S300). An example of the maximum SAS frame length is 1024 bytes.

If the transfer standby data amount is smaller than the maximum SAS frame length (Step S300: YES), the drive 3 transfers all the transfer standby data to the SAS adapter 4 (Step S301) and finishes the processing.

If the transfer standby data amount is not smaller than the maximum SAS frame length (Step S300: NO), the drive 3 executes the subsequent processing (Step S302). That is, the drive 3 determines whether misalignment has occurred or not (Step S302). The drive 3 calculates a total sum value of the offset value 425 and the data amount having been transferred so far, for example. Then, the drive 3 calculates a remainder when the total sum value is divided by the cache line size 412. When this remainder is “0”, the drive 3 may determine that misalignment has not occurred, while if this remainder is “other than 0”, the drive 3 may determine that misalignment has occurred.

When misalignment has not occurred (Step S302: NO), the drive 3 extracts data corresponding to the maximum SAS frame length from the buffer memory and generates an SAS frame storing the extracted data. Then, the drive 3 transmits the generated SAS frame to the SAS adapter 4 (Step S303) and returns to Step S300.

When misalignment has occurred (Step S302: YES), the drive 3 extracts the data corresponding to a value obtained by subtracting a portion of misalignment (that is, the remainder calculated above) from the maximum SAS frame length from the buffer memory and generates the SAS frame storing the extracted data. Then, the drive 3 transfers the generated SAS frame to the SAS adapter 4 (Step S304) and returns to Step S300.

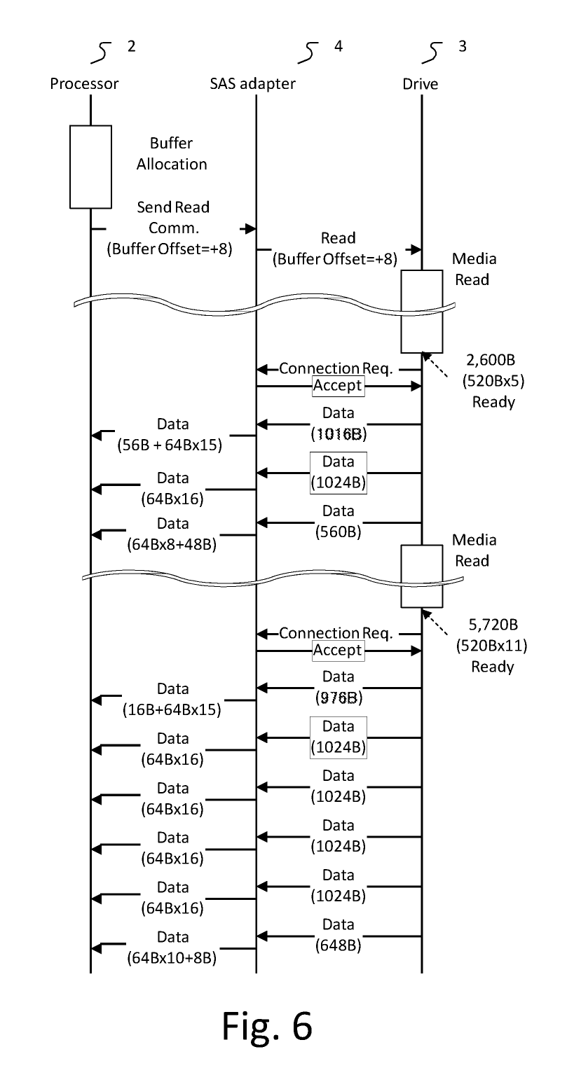

As described above, even if the drive 3 is capable of transfering the data for the maximum SAS frame length, it does not necessarily transfer all the data to the SAS adapter 4 but determines a data amount to be transferred by considering misalignment. As a result, the number of occurrence times of read-modify-write in the memory 5 can be reduced. A typical example of this processing will be described below by using FIG. 6.

FIG. 6 illustrates a typical example of the processing in which the data read from the drive 3 is stored in the memory 3.

The processor 2 reserves the buffer area for storing the read data in the memory 5. It is assumed that a beginning of this reserved buffer area is offset from a boundary of the cache line 200 by 8 bytes. Thus, the processor 2 transmits read information including an offset value “8 bytes” to the SAS adapter 4. When the SAS adapter 4 receives this read information, it transmits the read command 42 which sets “8 bytes” to the offset value 425 to the drive 3.

When the drive 3 receives this read command 42, it reads the data from the sector and stores it in the buffer memory in the drive 3. Then, the drive 3 transmits a connection request to the SAS adapter 4 at timing when the data of 2600 bytes (=520 bytes×5 sectors) is stored in the buffer memory, for example.

The drive 3 extracts the data from the buffer memory based on the processing illustrated in FIG. 5 and generates the SAS frame. Since the offset value 425 of the read command 42 is “8 bytes” (that is, since misalignment has occurred), the drive 3 extracts the data for “1016 bytes” portion obtained by subtracting the 8 bytes portion from the maximum SAS frame length (1024 bytes) from the buffer memory and generates a first SAS frame. Then, the drive 3 transfers the generated first SAS frame to the SAS adapter 4.

The SAS adapter 4 which received the first SAS frame divides the data (1016 bytes) of the SAS frame into packets which matches a size (64 bytes) of the cache line 200 of the memory 5. At this time, in the cache line 200 on the first stage in the buffer area of the memory 5, the data for the 8 bytes portion from the beginning has been stored. Thus, the SAS adapter 4 generates one packet containing the data of 56 bytes (=64 bytes−8 bytes) from the beginning of the data of 1016 bytes. Moreover, the SAS adapter 4 divides the remaining data of 960 bytes into three packets each having 256 bytes. Then, the SAS adapter 4 delivers each packet to the processor 2. The processor 2 applies read-modify-write to the packet including 56 bytes to the cache line 200 on the first stage of the buffer area and writes each packet of 256 bytes in the cache line 200 on the second to 16^{th} stages of the buffer area.

Moreover, the drive 3 extracts the data (1024 bytes) for the maximum SAS frame length portion from the buffer memory and generates a second SAS frame. It is because the data of the second SAS frame can be written from the beginning of the cache line 200 of the memory 5 (that is, since an offset does not occur). Then, the drive 3 transmits the generated second SAS frame to the SAS adapter 4.

The SAS adapter 4 which received the second SAS frame divides the data (1024 bytes) in the SAS frame into four packets each having 256 bytes. Then, the SAS adapter 4 delivers each packet to the processor 2. The processor 2 writes each packet in the cache line on 17^{th} to 32^{nd} stages of the buffer area.

Subsequently, the drive 3 extracts the remaining data (560 bytes) from the buffer memory and generates a third SAS frame. Then, the drive 3 transfers the generated third SAS frame to the SAS adapter 4.

The SAS adapter 4 which received the third SAS frame divides the data (560 bytes) of the SAS frame into two packets each having 256 bytes and one packet containing the remaining data of 48 bytes. Then, the SAS adapter 4 delivers each packet to the processor 2. The processor 2 writes each packet of 256 bytes in the cache line 200 on the 33^{rd} to 40^{th} stages of the buffer area and applies read-modify-write to the packet containing the data of 48 bytes to the cache line on the 41^{st} stage of the buffer area.

According to the processing described above, the number of occurrence times of the read-modify-write to the cache line 200 of the memory 5 is twice.

After that, it is assumed that data of 5720 bytes (=520 bytes×11 sectors) is stored in the buffer memory of the drive 3. In this case, since misalignment of “48 bytes” has occurred in the cache line on the 41^{st} stage of the buffer area, the drive 3 extracts the data of “976 bytes (=1024 bytes−48 bytes)” portion from the buffer memory and generates a first SAS frame. Then, the drive 3 transfers the generated first SAS frame to the SAS adapter 4.

Moreover, the drive 3 transmits the second to fifth SAS frames having 1024 bytes to the SAS adapter 4. Lastly, the drive 3 transfers the sixth SAS frame of 648 bytes to the SAS adapter 4. The SAS adapter 4 which received these SAS frames delivers the packets obtained by division similarly to the above to the processor 2. That is, the first packet size of the first SAS frame is 16 bytes, the last packet size of the sixth SAS frame is 8 bytes, and the other packet size is 256 bytes. Thus, the number of occurrence times of the read-modify-write to the cache line of the memory 5 is twice similarly to the above.

If the drive does not give consideration as above but transmits the maximum SAS frame length to the SAS adapter 4, processing would be as follows. For the data of 2600 bytes stored in the buffer memory in the drive, the drive makes the first and second SAS frames with 1024 bytes and the third SAS frame with 552 bytes. The SAS adapter which received the first SAS frame divides it into the packets and delivers it to the processor 2 similarly to the above. In this case, in storing of the first and last packets in the cache line 200, the processor 2 needs to execute the read-modify-write. For the second and third SAS frames, the processor 2 similarly needs to execute read-modify-write in storing of the first and last packets in the cache line 200. That is, the number of occurrence times of the read-modify-write to the cache line 200 of the memory 5 becomes 6. Moreover, for the data of 5720 bytes stored in the buffer memory of the drive, the drive makes the first to fifth SAS frames of 1024 bytes and the sixth SAS frame of 600 bytes. In this case, the number of occurrence times of the read-modify-write to the cache line of the memory 5 is 12.

That is, in the example in FIG. 6, the read-modify-write which occurred 18 times in total (=6 times+12 times) in the past can be reduced to the total of 4 times according to this embodiment. According to this embodiment, since the drive 3 considers an offset from the boundary of the cache line 200 in the memory 5 and adjusts the size of the first SAS frame, the number of occurrence times of the read-modify-write in the memory 5 can be reduced. Thus, according to this embodiment, the throughput of the memory 5 can be improved.

### Embodiment 2

Embodiment 2 is an example in which the SAS adapter 4 specifies a write destination in the memory 5 of the data of the SAS frame transferred from the drive 3 to a higher speed. Description of contents similar to those of the embodiment 1 will be omitted.

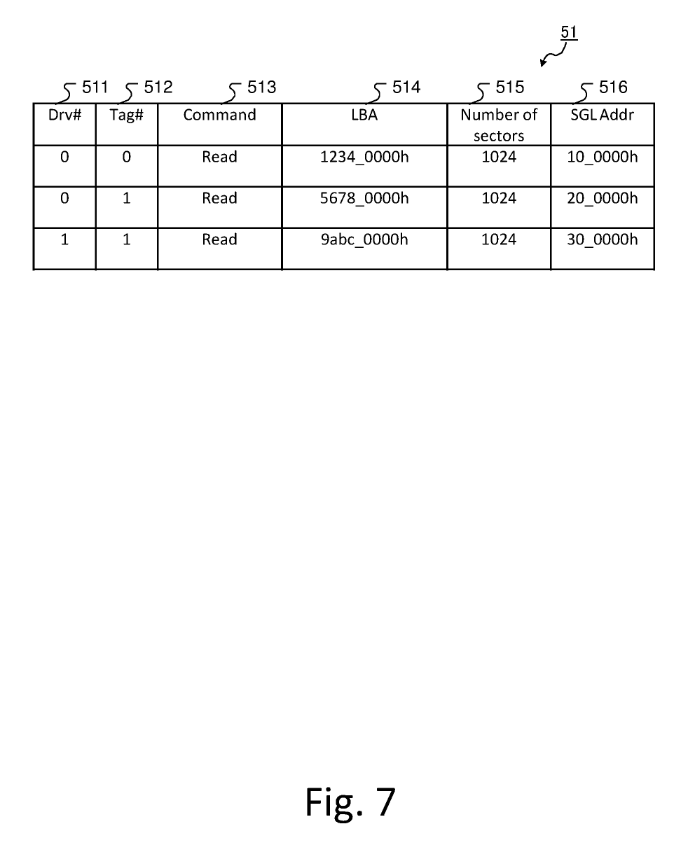

FIG. 7 illustrates a configuration example of a command management list 51.

The command management list 51 is a list for the SAS adapter 4 to manage the command transmitted to the drive 3. The command management list 51 may be generated by software operating on the processor 2 and stored in the memory 5. The command management list 51 may be referred to from the SAS adapter 4. The command management list 51 may have a drive number 511, a tag number 512, a command 513, an LBA 514, the number of sectors 515, and an SGL address 516 as field values.

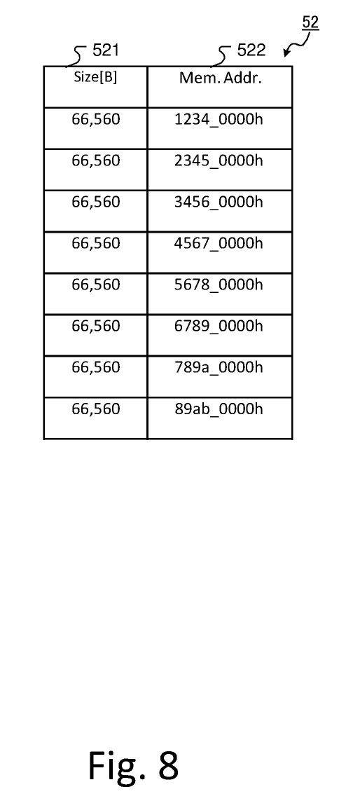

The drive number 511 is a number for identifying the drive 3. The tag number 512 is a number for identifying each command when a plurality of commands is transmitted to one drive 3. The command 513 indicates a type of the command transmitted to the drive 3. Examples of the command 513 are a “read command” and a “write command”. The LBA 514 is a beginning address of a sector which is a target of the command 513. The number of sectors 515 is the number of the sectors targeted by the command 513. The SGL address 516 is an address (corresponding to a pointer to the SGL) of a storage destination of the SGL. Details of the SGL will be described later (see FIG. 8).

A record with the drive number 511 “0” and the tag number 512 “0” in the command management list 51 illustrated in FIG. 7 indicates that to this drive 3 with the drive number 511 “0”, the “read command” (513) targeted to an area from the LBA 514 “12340000 h” to the “1024 sector” (515) has been issued, and the SGL having information relating to the storage destination of the read data is stored in the address “100000 h” (516) on the memory 5.

FIG. 8 illustrates a configuration example of the SGL 52.

In the SGL 52, the address on the memory 5 is stored. The SGL 52 may be generated by the software operating on the processor 2 and stored in the memory 5. The SGL 52 may be referred to from the SAS adapter 4. As illustrated in FIG. 7, the SGL address 516 of the record in the command management list 51 indicates the storage destination of the SGL 52 corresponding to the record.

The SGL 52 may have a size 521 and a memory address 522 as field values. The size 521 is a size of an area on the memory 5. The memory address 522 is an address of a storage destination/storage source on the memory 5.

The SGL 52 illustrated in FIG. 8 indicates that if the command 513 is the “read command”, the storage destination for a “66560 bytes” (521) portion from the beginning of the read data is an area of the memory address 522 “12340000 h”, and the storage destination for the subsequent “66560 byte” portion is an area of the memory address 522 “23450000 h”.

The SGL 52 illustrated in FIG. 8 indicates that if the command 513 is the “write command”, the storage source for the “66560 bytes” (521) portion from the beginning of the write data is an area of the memory address 522 “12340000 h” and the storage source for the subsequent “66560 bytes” portion is an area of the memory address 522 “23450000 h”.

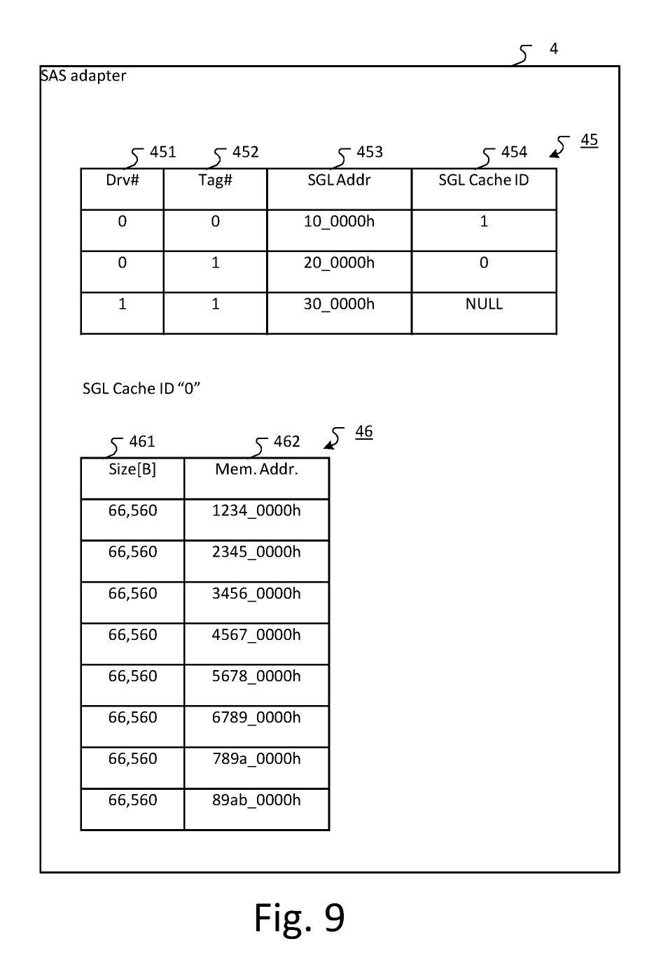

FIG. 9 illustrates a configuration example of an in-process command management list 45 and an SGL cache 46.

The SAS adapter 4 may hold some in the plurality of SGL 52 stored on the memory 5 in a predetermined internal memory as the SGL cache 46. The SGL cache 46 has a size 461 and a memory address 462 as field values. The size 461 and the memory address 462 are similar to the size 521 and the memory address 522 in FIG. 8, respectively.

Moreover, the SAS adapter 4 may hold information relating to the command having been transmitted to the drive 3 and also unfinished commands in the predetermined internal memory as the in-process command management list 45.

The in-process command management list 45 has a drive number 451, a tag number 452, an SGL address 453, and an SGL cache flag 454 as field values. The drive number 451, the tag number 452, and the SGL address 453 are similar to the drive number 511, the tag number 512, and the SGL address 516 in FIG. 7, respectively.

The SGL cache ID 454 is an identifier of the SGL cache 46 held in the SAS adapter 4. When the SGL cache 46 is not held, the SGL cache ID 454 may be “NULL”.

The record with the drive number 451 “0” and the tag number 452 “1” in the in-process command list 45 illustrated in FIG. 9 indicates that the command with the tag number 452 “1” transmitted to the drive 3 with this drive number 451 “0” is unfinished. Moreover, it also indicates that the SGL cache 46 corresponding to this command is held in the SGL adapter 4 as the SGL cache ID 454 “0”.

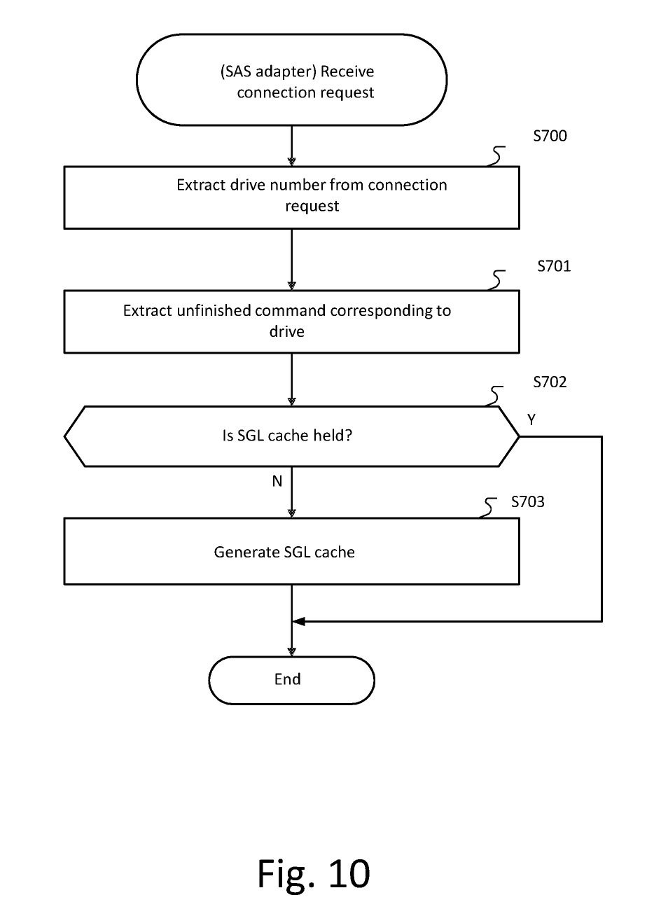

FIG. 10 is a flowchart illustrating a processing example of the SAS adapter 4 having received a connection request from the drive 3.

When the SAS adapter 4 receives the connection request from the drive 3, it extracts the drive number from the connection request (Step S700).

Then, the SAS adapter 4 searches a record (unfinished command) which matches the extracted drive number in the in-process command management list 45. When a plurality of the records is discovered, the SAS adapter 4 selects the oldest registered record (the oldest unfinished command) (Step S701).

The SAS adapter 4 refers to the SGL cache ID 454 included in the selected record and determines whether the SGL cache 46 is held or not (Step S702). If the SGL cache 46 is held (Step S702: YES), the SAS adapter 4 finishes this processing.

If the SGL cache 46 is not held (Step S702: NO), the SAS adapter 4 obtains the SGL 52 corresponding to the selected record from the memory 5 and holds it therein as the SGL cache 46 (Step S703). Then, the SAS adapter 4 finishes this processing.

As a result, at timing when the connection request is received from the drive 3, the SGL 52 corresponding to the oldest unfinished command is held inside the SAS adapter 4 as the SGL cache 46.

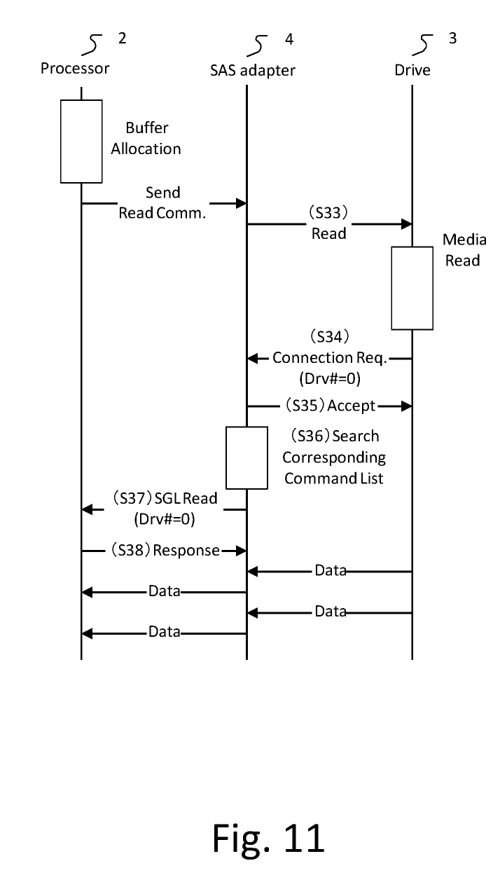

FIG. 11 is a sequence chart illustrating a processing example in which the data read from the drive 3 is stored in the memory 5 through the SAS adapter 4.

As described by using FIG. 6, when the drive 3 receives the read command 42 (Step S33), it reads the data from the storage medium and stores it in the buffer memory in the drive 3.

Then, the drive 3 transmits the connection request to the SAS adapter 4 (Step S34) at timing when it enters the transfer standby state of the SAS frame. This connection request may include the drive number of this drive 3.

When the SAS adapter 4 receives this connection request, it returns an acceptance reply to this connection request to the drive 3 (Step S35). As a result, the connection is formed between the drive 3 and the SAS adapter 4.

Moreover, the SAS adapter 4 may execute the following processing by using reception of this connection request as a trigger. That is, the SAS adapter 4 searches the oldest unfinished command which matches the drive number included in this connection request from the in-process command management list 45 as illustrated in FIG. 10 and holds the SGL 52 corresponding to the discovered oldest unfinished command therein as the SGL cache 46 (Steps S36, S37, and S38).

As a result, the SAS adapter 4 can know the storage destination of the data to be transferred from the drive 3 after that in the memory 4 from the SGL cache 46. Moreover, by holding the SGL cache 46 corresponding to the oldest unfinished command, a high cache hit rate can be realized by smaller SGL cache 46. Thus, the data can be stored in the memory 5 at a higher speed as compared with a case where the SGL 52 is obtained from the memory 5 at timing of reception of the data. That is, the throughput of the storage system 1 can be improved.

### Embodiment 3

Embodiment 3 is a variation of the embodiment 2. A difference from the embodiment 2 will be described.

Description of contents similar to the embodiment 1 or 2 will be omitted.

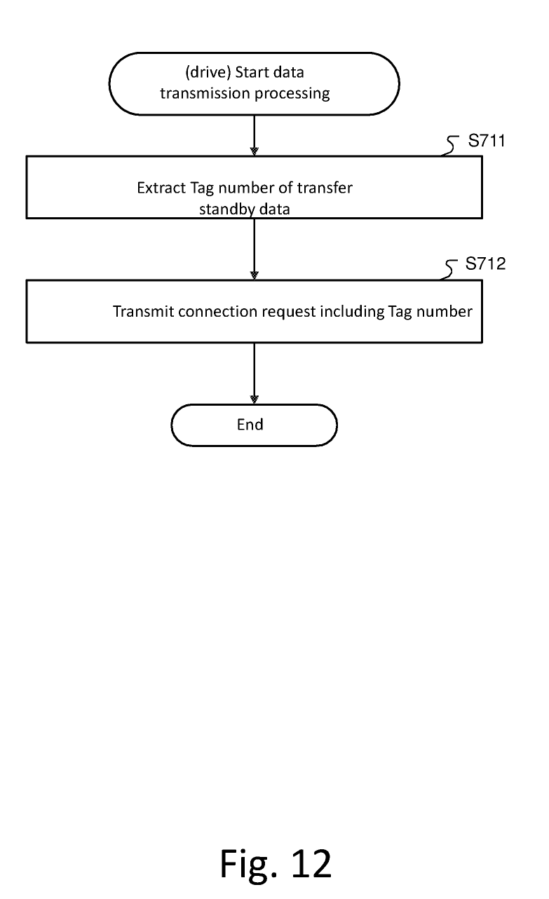

FIG. 12 is a flowchart illustrating a processing example of transmitting a connection request by the drive 3 to the SAS adapter 4.

At timing when the SAS frame enters a transfer standby state, the drive 3 specifies the tag number of the transfer standby SAS frame (Step S711). Then, the drive 3 generates a connection request including the specified tag number and the drive number of the drive 3 and transmits it to the SAS adapter 4 (Step S712). The tag number included in this connection request is an example of hint information for notifying the data to be transferred after that to the SAS adapter 4.

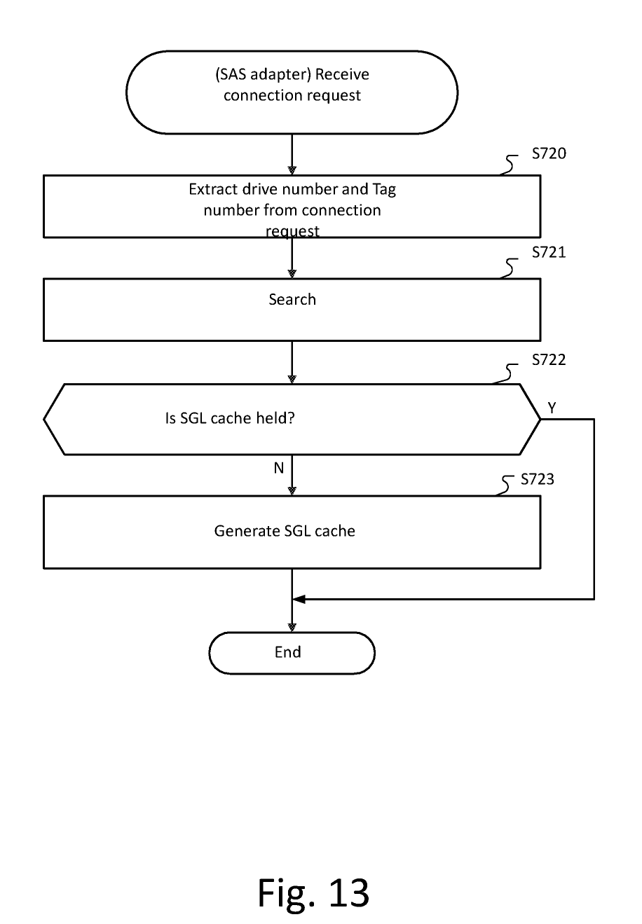

FIG. 13 is a flowchart illustrating a processing example of the SAS adapter 4 which receives the connection request from the drive 3.

When the SAS adapter 4 receives the connection request from the drive 3, it extracts the drive number and the tag number from the connection request (Step S720).

Then, the SAS adapter 4 searches a record (unfinished command) which matches the extracted drive number and tag number from the in-process command management list 45 (Step S721).

The SAS adapter 4 refers to the SGL cache ID 454 included in the record discovered by the search and determines whether the SGL cache 46 is held or not (Step S722).

When the SGL cache 46 is held (Step S722: YES), the SAS adapter 4 finishes this processing.

When the SGL cache 46 is not held (Step S722: NO), the SAS adapter 4 obtains the SGL 52 corresponding to the discovered record from the memory 5 and holds it therein as the SGL cache 46 (Step S723). Then, the SAS adapter 4 finishes this processing.

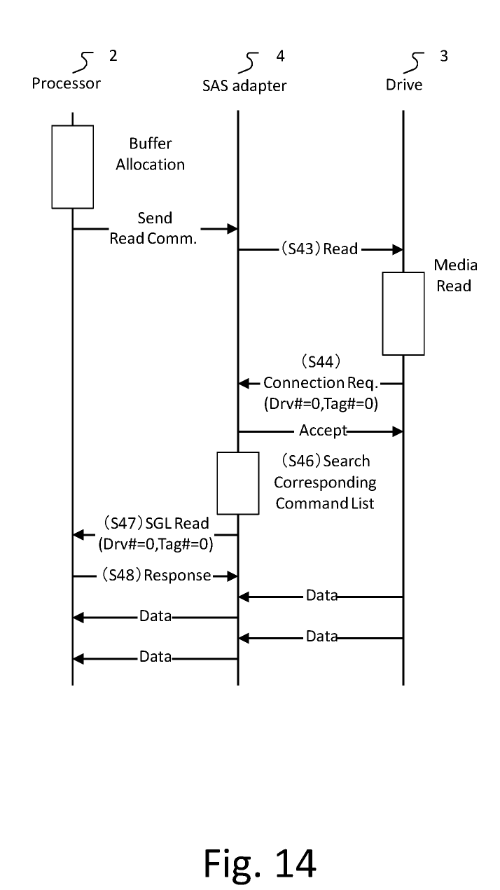

FIG. 14 is a sequence chart illustrating a processing example in which the data read from the drive 3 is stored in the memory 5 through the SAS adapter 4.

As described by using FIG. 6, when the drive 3 receives the read command 42 (Step S43), it reads the data from the storage medium and stores it in the buffer memory in the drive 3.

Then, the drive 3 transmits a connection request to the SAS adapter 4 (Step S44) at timing when it enters the SAS frame transfer standby state. This connection request may include the drive number of this drive 3 and the tag number relating to this SAS frame made transferable.

The SAS adapter 4 executes the following processing by using reception of this connection request as a trigger. That is, the SAS adapter 4 searches an unfinished command which matches the drive number and the tag number included in this connection request from the in-process command management list 45 as illustrated in FIG. 13 and holds the SGL 52 corresponding to the discovered unfinished command therein as the SGL cache 46 (Steps S46, S47, and S48).

As a result, the SAS adapter 4 can know the storage destination of the data to be transferred from the drive 3 after that in the memory 4 from the SGL cache 46. Thus, the data can be stored in the memory 5 at a higher speed as compared with the case where the SGL 52 is obtained from the memory 5 at timing of reception of the data. That is, the throughput of the memory 5 can be improved.

Several embodiments have been described but they are exemplifications for describing the present invention and are not intended to limit the scope of the present invention only to these embodiments. The present invention can be embodied in other various forms. For example, the contents of the embodiment 2 or 3 may be combined with the contents of the embodiment 1. Moreover, the protocol between the SAS adapter and the storage drive may be those other than the SAS protocol. Moreover, the protocol between the SAS adapter and the processer may be those other than the PCIe protocol.

The contents relating to the embodiments can be expressed as follows:

### (Expression 1)

A storage system including:

a processor;

a memory accessed on a unit of a memory partition, the memory partition having a predetermined size;

a storage drive; and

an interface device interfacing data communication between the processor and the storage drive, wherein

the storage drive is configured to:

determine a size of transfer data based on an offset value which is a value relating to a size between a storage area in the memory for the transfer data to be transferred to the interface device and a predetermined position of the partition in the memory to which at least a part of the storage area belongs; and
transfer the transfer data of the determined size to the interface device;

the interface device is configured to divide the transfer data into packets and transfer them to the processor; and

the processor is configured to store the packet transferred from the interface device in the memory on a unit of a partition.

### (Expression 2)

The storage system according to the expression 1, wherein the offset value is a value relating to a size between a beginning of a storage area in the memory for the transfer data and a beginning of a partition in the memory to which the beginning of the storage area belongs.

### (Expression 3)

The storage system according to the expression 1 or 2, wherein the offset value is included in a read command issued from the interface device to the storage drive.

### (Expression 4)

The storage system according to any one of the expressions 1 to 3, wherein the size of the transfer data is a size obtained by subtracting the offset value from a maximum size that the transfer data can take.

### (Expression 5)

The storage system according to any one of the expressions 1 to 4, wherein the storage drive is configured to calculate the offset value relating to a subsequent transfer data based on an amount of the transfer data having been transferred to the interface device and to determine the size of the subsequent transfer data based on the calculated offset value.

### (Expression 6)

The storage system according to any one of the expressions 1 to 5, wherein the storage drive is configured to:

transfer, when an amount of transfer standby data to the interface device is less than the maximum size that the transfer data can take, all the transfer standby data to the interface device;

determine, when the amount of the transfer standby data to the interface device is not less than the maximum size that the transfer data can take, whether the offset value is “0” or not;

transfer, when the offset value is “0”, data having the maximum size that the transfer data can take in the transfer standby data to the interface device; and

transfer, when the offset value is not “0”, data having the size obtained by subtracting the offset value from the maximum size that the transfer data can take in the transfer standby data to the interface device.

### (Expression 7)

The storage system according to any one of the expressions 1 to 6, wherein

data communication between the interface device and the processor is based on specifications of PCI-Express;

the data communication between the interface device and the storage drive is based on specifications of SAS (Serial Attached SCSI); and

a maximum size that the transfer data can take is a value determined based on the specifications of SAS.

### (Expression 8)

A storage system including:

a processor;

a memory;

a storage drive; and

an interface device interfacing data communication between the processor and the storage drive, wherein

the memory is configured to store command management information associating a read command issued by the interface device to the storage drive with a storage area in the memory of the data read by the read command;

the interface device is configured to hold in-process command management information generated by extracting information relating to an unfinished read command in the read commands issued to the storage drive from the command management information; and

the interface device is configured to specify the storage area in the memory for the transfer data based on the in-process command management information.

### (Expression 9)

The storage system according to the expression 8, wherein

the interface device is configured to generate the in-process command management information at timing when a connection request for transfer of the transfer data is received from the storage drive.

### (Expression 10)

The storage system according to the expression 8 or 9, wherein

the interface device is configured to generate the in-process command management information by extracting information relating to an unfinished read command in the read commands issued to the storage drive which is a transmission source of the connection request from the command management information.

### (Expression 11)

The storage system according to the expression 10, wherein

the interface device is configured to generate the in-process command management information by extracting information relating to an oldest issued unfinished read command when there is a plurality of unfinished read commands.

### (Expression 12)

The storage system according to the expression 8 or 9, wherein

the read command includes distinction information for discriminating the read command from other read commands;

the command management information further associates the read command with the distinction information;

the storage drive is configured to transmit a connection request including the distinction information of the read command relating to the transfer data to the interface device; and

the interface device is configured to generate the in-process command management information by extracting information relating to the unfinished read command associated with the distinction information.

### (Expression 13)

A storage control method wherein

a storage drive is configured to:

obtain read data from a storage area;

determine a size of transfer data based on an offset value which is a value relating to a size between the storage area in a memory accessed on a unit of a partition, the partition having a predetermined size, and a predetermined position of the partition in the memory to which at least a part of the storage position belongs; and
transfer the transfer data of the determined size to an interface device;

the interface device is configured to divide the transfer data into packets and to transfer them to the processor when the interface device receives the transfer data from the storage drive; and

the processor is configured to store the packet in the memory on a unit of a partition when the processor receives the packet from the interface device.

### (Expression 14)

A storage control method wherein

an interface device interfacing data communication between a processor and a storage drive is configured to:

generate in-process command management information by extracting information relating to an unfinished read command in the read commands issued to the storage drive from command management information which is command management information stored in a memory and associates a read command issued by the interface device to the storage drive with a storage area in the memory of the data to be read by the read command and holds the generated in-process command management information; and

specify the storage area in the memory for the transfer data based on the in-process command management information.

### REFERENCE SIGNS LIST

1: storage system, 2: processor, 3: drive, 4: SAS adapter, 5: memory

1. A storage system comprising:
a processor;
a memory accessed on a unit of a partition, the partition having a predetermined size;
a storage drive; and
an interface device interfacing data communication between the processor and the storage drive, wherein
the storage drive is configured to:
determine a size of transfer data based on an offset value which is a value relating to a size between a storage area in the memory for the transfer data to be transferred to the interface device and a predetermined position of the partition in the memory to which at least a part of the storage area belongs; and
transfer the transfer data of the determined size to the interface device;
the interface device is configured to divide the transfer data into packets and transfer them to the processor; and
the processor stores the packet transferred from the interface device in the memory on a unit of a partition.

2. The storage system according to claim 1, wherein the offset value is a value relating to a size between a beginning of a storage area in the memory for the transfer data and a beginning of a partition in the memory to which the beginning of the storage area belongs.

3. The storage system according to claim 1, wherein the offset value is included in a read command issued from the interface device to the storage drive.

4. The storage system according to claim 2, wherein the size of the transfer data is a size obtained by subtracting the offset value from a maximum size that the transfer data can take.

5. The storage system according to claim 2, wherein the storage drive is configured to calculate the offset value relating to a subsequent transfer data based on an amount of the transfer data having been transferred to the interface device and to determine the size of the subsequent transfer data based on the calculated offset value.

6. The storage system according to claim 4, wherein the storage drive is configured to:
transfer, when an amount of transfer standby data to the interface device is less than the maximum size that the transfer data can take, all the transfer standby data to the interface device;
determine, when the amount of the transfer standby data to the interface device is not less than the maximum size that the transfer data can take, whether the offset value is “0” or not;
transfer, when the offset value is “0”, data having the maximum size that the transfer data can take in the transfer standby data to the interface device; and
transfer, when the offset value is not “0”, data having the size obtained by subtracting the offset value from the maximum size that the transfer data can take in the transfer standby data to the interface device.

7. The storage system according to claim 4, wherein
data communication between the interface device and the processor is based on specifications of PCI-Express;
the data communication between the interface device and the storage drive is based on specifications of SAS (Serial Attached SCSI); and
a maximum size that the transfer data can take is a value determined based on the specifications of SAS.

8. The storage system according to claim 1, wherein
the memory is configured to store command management information associating a read command issued by the interface device to the storage drive with a storage area in the memory of the data read by the read command;
the interface device is configured to hold in-process command management information generated by extracting information relating to an unfinished read command in the read commands issued to the storage drive from the command management information; and
the interface device is configured to specify the storage area in the memory for the transfer data based on the in-process command management information.

9. The storage system according to claim 8, wherein
the interface device is configured to generate the in-process command management information at timing when a connection request for transfer of the transfer data is received from the storage drive.

10. The storage system according to claim 9, wherein
the interface device is configured to generate the in-process command management information by extracting information relating to an unfinished read command in the read commands issued to the storage drive which is a transmission source of the connection request from the command management information.

11. The storage system according to claim 10, wherein
the interface device is configured to generate the in-process command management information by extracting information relating to an oldest issued unfinished read command when there is a plurality of unfinished read commands.

12. The storage system according to claim 10, wherein
the read command includes distinction information for discriminating the read command from other read commands;
the command management information further associates the read command with the distinction information;
the storage drive is configured to transmit a connection request including the distinction information of the read command relating to the transfer data to the interface device; and
the interface device is configured to generate the in-process command management information by extracting information relating to the unfinished read command associated with the distinction information.

13. A storage control method wherein
a storage drive is configured to:
obtain read data from a storage area;
determine a size of transfer data based on an offset value which is a value relating to a size between the storage area in a memory accessed on a unit of a partition, the partition having a predetermined size, and a predetermined position of the partition in the memory to which at least a part of the storage position belongs; and
transfer the transfer data of the determined size to an interface device;
the interface device is configured to divide the transfer data into packets and to transfer them to the processor when the interface device receives the transfer data from the storage drive; and
the processor is configured to store the packet in the memory on a unit of a partition when the processor receives the packet from the interface device.
